(19) United States
(12) Patent Application Publication
(10) Pub. No.: US 2025/0124677 A1
(43) Pub. Date: Apr. 17, 2025

(54) INTEGRATED VISUALIZATION PLATFORM FOR SMART HOME CONTROL

(71) Applicant: Florida Power & Light Company, Juno Beach, FL (US)

(72) Inventors: Lawrence Jacob Oks, Palm Beach Gardens, FL (US); Kara L. Fuller, Hobe Sound, FL (US); Jose L. Medina, Tequesta, FL (US)

(21) Appl. No.: 18/999,204

(22) Filed: Dec. 23, 2024

Related U.S. Application Data
(63) Continuation-in-part of application No. 18/307,892, filed on Apr. 27, 2023.
(60) Provisional application No. 63/490,018, filed on Mar. 14, 2023.

(51) Int. Cl. G06T 19/00; G01R 21/133; G05B 13/02; G06V 20/20

(52) U.S. Cl. CPC G06T 19/006; G01R 21/133; G05B 13/028; G06V 20/20; G06T 2200/24; G06T 2210/56

(57) ABSTRACT

A computer-implemented method for controlling energy consumption in an extended reality (XR) space involves accessing an image of a real-world space and using image recognition to identify an energy-related object. The method stores the object's 3D coordinates and retrieves specific energy information, including real-time or historical consumption data measured by a device, independent of generic family or model data. Using the stored coordinates, the method generates a virtual or mixed reality image by overlaying a computer-generated indicator near the object. When a user selects the indicator, the method displays the specific energy information within the XR environment. The method also enables the user to adjust the object's energy consumption via a wired or wireless communication interface, allowing real-time control. This approach integrates image recognition, data visualization, and remote control to streamline energy management within an XR environment.

### CROSS-REFERENCE TO RELATED APPLICATIONS

This application is based upon and claims priority from prior U.S. patent application Ser. No. 18/307,892, filed on Apr. 27, 2023, entitled “Immersive Interactive Energy Assessment”, which is based on and claims priority from U.S. Provisional Patent Application No. 63/490,018, filed on Mar. 14, 2023, entitled “Immersive Interactive Energy Assessment”, the entire disclosure each of the aforementioned applications is incorporated by reference in their entirety.

### FIELD OF THE DISCLOSURE

The present disclosure generally relates to an extended reality system for controlling the energy consumption of home devices using synthetically generated images.

### BACKGROUND

Data analytics tools provide users with valuable insights into their energy consumption patterns. These tools can analyze usage data, identify trends, and even predict future consumption. However, while these tools excel at presenting information, they do not enable users to act on these insights. Although users can identify areas where they are wasting energy or which devices are using the most power, users often lack the means to make immediate adjustments that could reduce waste and improve efficiency.

In contrast, smart home control systems allow users to manage various aspects of their home environment, such as lighting, heating, cooling, and appliances. These systems can automate routines, respond to user commands, and integrate with voice assistants. However, they usually lack detailed analytics, making it difficult for users to understand the broader effects of their actions on overall energy consumption. As a result, users may struggle to optimize their energy usage effectively.

### SUMMARY OF THE INVENTION

The disclosed system and method combine virtual reality techniques with a consumer's real-world space to identify ways to reduce energy consumption and their attendant carbon footprint through an immersive energy assessment.

Once an object that is related to the consumption of energy in the consumer's real-world space is identified, the system is able to present energy information that is specific to that object. This is in contrast to generic information such as an Energy Star rating. The specific energy information in one example is derived from data from many sources, including smart electric meters, smart appliances, smart home equipment, Internet of Things equipment, smart thermostats, smart speakers, and in-line watt meters.

Disclosed is a computer-implemented method and system for controlling the energy consumption of an object in an extended reality space. The method begins with accessing at least one image of a real-world space. The real-word image can be a virtual image. Image recognition is used to identify an object related to energy consumption in the image in the real-world space. In one example, a label from a user, such as a QR code, bar code, or simple text description, is used to identify the object related to energy consumption in the image. The user label may be used in combination with image recognition techniques.

Next, a 3D coordinate of the object related to energy consumption in the image that has been identified is stored. The identified object is used to access corresponding specific energy information. The specific energy information is a real-time or historical energy consumption, measured with a measuring device, for the identified object. The specific energy information is independent of generic energy information for a family or model of the identified object.

The specific energy information is a real-time or historical energy consumption, measured with the measuring device that is a smart meter coupled to a plurality of parallel coupled energy consumption-related objects, including the identified object. The measuring device analyzes the power consumption of the plurality of parallel coupled energy consumption-related objects to determine the energy consumption of the identified object. In another example, the specific energy information is a real-time or historical energy consumption, measured with the measuring device that is an on-call device coupled to the identified object. One example of an on-call device is FPL's On Call program, which helps customers reduce their energy costs. When energy demand is high, FPL sends a signal to the on-call device to temporarily turn off selected appliances, such as the air conditioner or water heater. This helps FPL manage the power grid and prevent blackouts. Another example is the energy consumption information from a smart electric meter, an appliance, smart home equipment, Internet of Things (IoT) equipment, smart thermostats, smart speakers, in-line watt meters, or any combination thereof.

The identified object may be one of appliances, HVAC, windows, range hoods, thermostats, doors, structural features, ceilings, HVAC vents, pool pumps, sprinkler pumps, or a combination thereof.

Next, a virtual reality image or mixed reality image is created by combining i) at least one computer-generated indicator of specific energy information near each identified object related to energy consumption with ii) the image of the real-world space using the stored 3D coordinates. A user selection is received of one of the computer-generated indicators of specific energy information. Presenting the specific energy information corresponding to the identified object related to energy consumption as part of the virtual reality image or the mixed reality image in response to receiving the user selection of the computer-generated indicator. The energy consumption of the identified object is adjusted through a wired or wireless communication interface to control the identified object.

A computer-implemented method for controlling energy consumption of an object within an extended reality (XR) space includes accessing at least one image of a real-world space and identifying, using image recognition, an object related to energy consumption within the image. The method involves storing the 3D coordinate corresponding to the identified object and accessing specific energy information for the object. This specific energy information includes real-time or historical energy consumption measured by a device and is independent of generic energy data for the object's family or model. Using the stored 3D coordinate, the method creates a virtual reality or mixed reality image by overlaying a computer-generated indicator near the identified object within the real-world space image. The method then receives a user selection of the computer-generated indicator and, in response, presents the specific energy information corresponding to the identified object as part of the virtual reality or mixed reality image. Finally, the method enables the user to adjust the energy consumption of the identified object through a wired or wireless communication interface, allowing direct control of the object.

A computer-implemented method for controlling energy consumption in an extended reality (XR) space involves accessing an image of a real-world space and using image recognition to identify an energy-related object. The method stores the object's 3D coordinates and retrieves specific energy information, including real-time or historical consumption data measured by a device, independent of generic family or model data.

Using the stored coordinates, the method generates a virtual or mixed reality image by overlaying a computer-generated indicator near the object. When a user selects the indicator, the method displays the specific energy information within the XR environment. The method also enables the user to adjust the object's energy consumption via a wired or wireless communication interface, allowing real-time control.

This approach integrates image recognition, data visualization, and remote control to streamline energy management within an XR environment.

### BRIEF DESCRIPTION OF THE DRAWINGS

The accompanying figures, where like reference numerals refer to identical or functionally similar elements throughout the separate views, and which together with the detailed description below are incorporated in and form part of the specification, serve to further illustrate various embodiments and to explain various principles and advantages all in accordance with the present disclosure, in which:

FIG. 1 illustrates an equipment image capture environment, according to an example;

FIG. 2 is an image of a top perspective view of a real-world residential space, according to an example;

FIG. 3 is a more detailed image of a kitchen area in FIG. 2, illustrating the identified objects with the computer-generated indicators in the virtual reality image, according to an example;

FIG. 4 is another image of the kitchen area in FIG. 3 illustrating the identified object as a refrigerator, according to an example;

FIG. 5 is an image of a hallway area in FIG. 2 illustrating the identified object as an HVAC thermostat, according to an example;

FIG. 6 is an image of a laundry room area in FIG. 2 illustrating the identified object as a clothes washer and dryer, according to an example;

FIG. 7 is an image of a garage area in FIG. 2 illustrating the identified object as an electric vehicle (EV) charger, according to an example;

FIG. 8 is an image of general information displayed in an open area of a real-world space in FIG. 2, according to an example;

FIG. 9A and FIG. 9B is a process flow of an immersive interactive energy assessment, according to an example;

FIG. 10 is a process flow of machine learning image training set creation, according to an example;

FIG. 11 is a block diagram of various methods of accessing specific energy information from an object related to energy consumption, according to an example;

FIG. 12 is a display of four properties in a portfolio compared side-by-side according to an example;

FIG. 13 is a display of solar production for four properties over time, according to an example.

FIG. 14 is a functional block diagram for providing advertisements in an immersive interactive environment, according to an example;

FIG. 15 is a functional block diagram for providing advertisements in an immersive interactive environment, according to an example;

FIG. 16 is a functional block diagram for controlling a device in an immersive interactive environment, according to an example;

FIG. 17 illustrates a process flow for controlling a device in an immersive interactive energy environment, according to an example; and

FIG. 18 illustrates a block diagram illustrating a processor, according to an example.

### DETAILED DESCRIPTION

As required, detailed embodiments are disclosed herein; however, it is to be understood that the disclosed embodiments are merely examples and that the systems and methods described below can be embodied in various forms. Therefore, specific structural and functional details disclosed herein are not to be interpreted as limiting but merely as a basis for the claims and as a representative basis for teaching one skilled in the art to variously employ the disclosed subject matter in virtually any appropriately detailed structure and function. Further, the terms and phrases used herein are not intended to be limiting, but rather to provide an understandable description.

### Non-Limiting Definitions

The term “3D measurements” refers to measurements, typically non-contact measurements, taken of an object to create a three-dimensional (3D) point cloud of an object that is dimensionally accurate and a photorealistic model of the object, such as through photogrammetry.

The terms “a” or “an”, as used herein, are defined as one or more than one. The term plurality, as used herein, is defined as two or more than two.

The term “adapted to” describes the hardware, software, or a combination of hardware and software that is capable of, able to accommodate or that is suitable to carry out a given function.

The term “another”, as used herein, is defined as at least a second or more.

The terms “camera” and “displays” are terms of convenience but do nevertheless describe an ordinary cell phone. A camera can be expanded to include any form of directional identification of the appliance—Optics, LiDAR, RFID, NFC, etc. and the display can be a cell phone with or without displaying augmentation of the appliance or a hand-held or head-worn stereoscopic display. Also, the information displayed can include both smart meter and cloud-based appliance information.

The term “class” or “classifier” or “label” is a class label applied to data input in a machine learning algorithm.

The term “configured to” describes hardware, software or a combination of hardware and software that is adapted to, set up, arranged, built, composed, constructed, designed, or that has any combination of these characteristics to carry out a given function.

The term “computer-generated image” means computer-generated image content brought into a real-world image to augment it.

The term “control” refers to direct or indirect communication between a user and a device utilizing a wired or wireless interface. This communication enables the user to adjust the device's energy consumption. The user can control the device using one or more of eye movements, hand gestures, and speech.

The term “coupled,” as used herein, is defined as “connected,” although not necessarily directly and not necessarily mechanically.

The term “energy consumption” as used herein, means related to the use of energy sources, including electricity, natural gas, oil, and includes both renewable and non-renewal sources of energy. Energy consumption can be specific to a device being viewed or generic, such as information that is applicable to all similar make and model numbers of the device.

The term “extended reality” is an umbrella term for all immersive technologies, including augmented reality (AR), virtual reality (VR), and mixed reality (MR).

The term “generic energy information” means general energy information, typically from a manufacturer or other agency for a given family or model of objects related to energy savings.

The terms “including” and “having,” as used herein, are defined as comprising (i.e., open language).

The term “image” refers to a spatial pattern of physical light comprised of known colors of the light spectrum, which may or may not be visible to the human eye. The term image includes both real-world images, such as a live view through a camera, as well as a virtual representation of a space.

The term “image editing software” means software for editing and manipulating images, such as Blender.org or Photoshop® from Adobe Inc.

The term “or” is intended to mean an inclusive “or” rather than an exclusive “or.” That is, unless specified otherwise or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

The term “object related to energy consumption” means insulation in walls, attic, foundation, hot water equipment, ventilation, smart thermostats, LEDs, smart power strips, appliances, solar hot water, solar photoelectric, electric vehicle chargers, window tint, replacement windows, and other energy-efficient technologies that improve energy savings and provide a reduction in a carbon footprint.

The term “photogrammetry” is a technique to extract three-dimensional measurements of an object to obtain reliable information, such as three-dimensional measurements, through processing and interpreting a series of photographic images. Photogrammetry may be complemented by techniques like LiDAR, laser scanners (using time of flight, triangulation or interferometry), white-light digitizers and any other technique that scans an area and returns x, y, z coordinates for multiple discrete points, commonly called “point clouds”.

The term “real-world”' means existing in reality, as opposed to one that is virtual, imaginary, simulated, theoretical or a computer-generated image.

The term “specific energy information” means energy information measured, whether real-time or historical data, and whether directly or inferred through a smart meter, for specific objects related to energy savings in a real-world space, typically appliances and other items or objects related to energy consumption.

The term “synthetic” means creating a computer-generated composite image combining computer-generated images with real-world images.

The term “variable attributes” means a changeable characteristic of a specific object in a family of objects that may be different from other objects in the same family of objects.

The term “uniform data format” means data in a given format, whether date format, time format, currency format, scientific format, text format, or fractional format, so that all values of data are presented in a single consistent format for a given category or criteria.

It should be understood that the steps of the methods set forth herein are not necessarily required to be performed in the order described, and the order of the steps of such methods should be understood to be merely exemplary. Likewise, additional steps may be included in such methods, and certain steps may be omitted or combined in methods consistent with various embodiments of the present device.

### Overview

Traditional solutions for energy management generally fall into two categories: data analytics and smart home control. Typically, these solutions operate in isolated silos, which means users either receive detailed information about their energy consumption or have the ability to manage specific devices. Still, they do not get both functionalities in a cohesive manner. While residential energy audit tools, smart home control platforms, and data analytics services exist as separate entities today, there is currently no integrated solution that combines 3D visualization of home layouts and devices, detailed energy usage analytics from smart meters, and direct control over IoT-enabled appliances within a single unified platform. Aspects of the claimed invention solve this issue of inefficient residential energy management by providing a comprehensive platform that integrates energy usage insights with direct control over consumption sources.

One aspect of the claimed invention is “See It, Control It”. This is an integrated software platform that combines 3D visualization capabilities to scan and render a home's layout along with detected appliances and devices. This aspect offers robust analytics on energy usage patterns using smart meter data, as well as direct IoT control over connected devices, all within a single intuitive interface. By visually mapping energy consumption to specific household objects, users can easily identify inefficiencies and directly optimize settings and schedules to reduce overall consumption. This platform leverages advanced data analytics, 3D scanning, computer vision, and IoT integration to create a first-of-its-kind residential energy command center.

The system effectively bridges the visualization of energy insights with the ability to enact changes through IoT control within the 3D home environment. Key innovations that advance the state of the art include tightly coupling energy usage visibility with control capabilities in one interface, creating a closed-loop system where users can implement energy-saving changes by directly controlling detected IoT devices, and enabling an open ecosystem for third-party integration to expand capabilities.

By cohesively combining multiple disparate technologies into one seamless system, this platform provides unprecedented visibility into energy consumption patterns directly tied to the ability to optimize usage through IoT control-a capability not offered by any existing residential energy or smart home platform today. The benefits include new customer controls over energy usage, improved customer satisfaction leading to a reduction in energy audit calls due to enhanced transparency, and integration into Demand Side Management (DSM) programs that can showcase customers' contributions to their community. Key potential benefits of this integrated platform also include proven residential energy and cost savings, cutting-edge AI-driven recommendations, a seamless experience from insight to action, robust data privacy and security, and an extensible open ecosystem. This pioneering residential energy optimization system stands out compared to existing fragmented solutions, with its unified visualization and control approach having applications that extend beyond residential settings to commercial and industrial energy management. Moreover, by enabling an open API and a third-party integration marketplace, the system could expand into adjacent smart home services, such as solar energy, EV charging, and generative AI for personalized recommendations.

Disclosed is a method to combine extended reality techniques with a consumer's real-world space to identify ways to reduce energy consumption and reduce their attendant carbon footprint through an immersive energy assessment.

Once an object that is related to the consumption of energy in the consumer's real-world space, i.e., residential house or commercial building, is identified, the system is able to present energy information that is specific to that object. This is in contrast to generic information such as an Energy Star rating. The specific energy information in one example is derived from data from many sources, including smart electric meters, smart appliances, smart home equipment, IoT equipment, smart thermostats, smart speakers, and in-line watt meters.

In one example, in a house with a washing machine and a microwave, the smart meter may identify the washing machine by long rhythmic power consumption and the microwave by short and high start currents. Then, a camera (e.g., a camera of a mobile device) would identify a specific washing machine, microwave manufacturer, and model number through a “Google Lens” type process. The invention then generalizes the manufacturer and model number information to an appliance type and then matches the appliance type identified by the smartmeter to display the corresponding power profile information.

The disclosed system builds towards virtualizing the field energy audit experience, as auditors can virtually collaborate in the home with the customer, exploring the home and its appliances to assess energy inefficiencies.

### Operating Environment

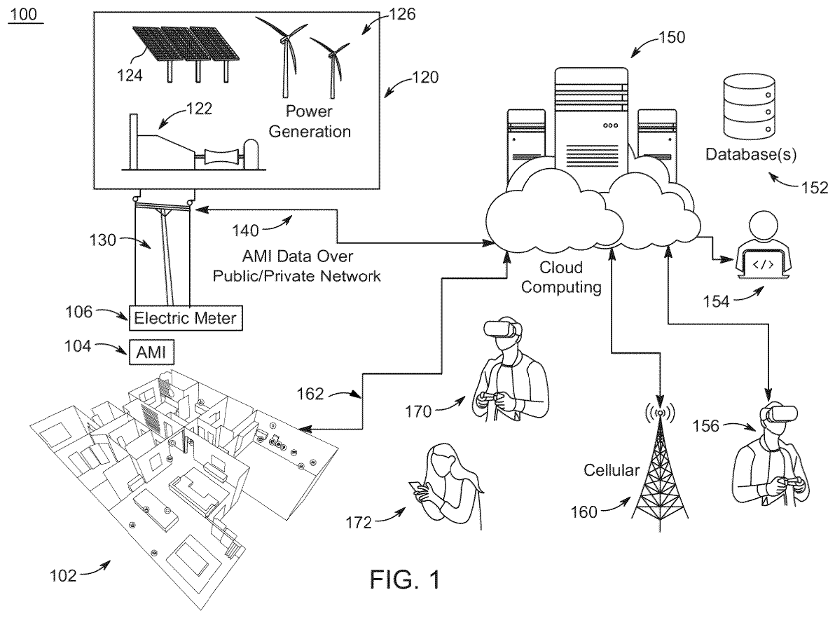

FIG. 1 shows one example of an operating environment 100 for performing an interactive energy assessment, including an electrical power “grid” used to provide electrical power to consumer premises 102, according to an example. The example shown in FIG. 1 depicts several examples of power generation components 120. Illustrated is a combined cycle gas generator 122, a solar array farm 124, and a wind farm 126. In further examples, operational contexts can include one power generation component, multiple collocated power generation components, power generation components that are physically separated and supply a common electrical power transmission or distribution system, any one or more power generation components, or combinations of these. These power generation components can be of any suitable type or design.

In this example, electrical power generated by one or more power generation components is provided to a power transmission system 130. The illustrated example depicts a transmission connection 130 that couples one or more sources within power generation components 120 to the consumer's premises 102. For simplicity, additional known transmission equipment is not shown as part of the transmission connection 130, such as suitable step-up transformers and long-distance transmission lines to convey the generated electrical power to remote power distribution networks and other electrical power consumers. A smart electric meter 106 is electrically coupled to the transmission connection 130 for the consumer's premises, as shown. In one example, the smart electric meter 106 is also electrically coupled to an advanced metering network (AMI) 104.

The electric meter 104 may include an AMI module 106 and a consumer's premises 102 interconnected through a smart grid, for example. In one embodiment, the AMI customer portal 154 provides customers with tools to compare monthly, daily, and hourly energy usage periods through a cloud computing platform 150. The customers may be able to access the data from database repository 152 on a real-time basis through the use of a wired network 162 to the consumer's premises 102 or wireless network 160. Alternatively, the data may be accessed in a near-real-time manner. The data may be collected by the AMI module 106 from a plurality of sources and then transmitted through the use of network 140 to the data repository 152. For example, the data may be collected from smart meters, Home Area Network (HAN) pricing, or any other component of the AMI. The system may also provide customers with analytical tools to be displayed/interacted with via mobile devices 156, 170, 172, and computing device 154, as part of the extended reality experience. The analytical tools may be for at least a graphical, a tabular, a numerical analysis, or the like of the customer's anticipated energy usage and generation data. The system may also provide the customers with an analytical tool for at least a graphical, tabular, numerical analysis or the like of the customer's historical energy usage and energy generation data.

Optionally, the system may also have a plurality of widgets customized and/or customized for individual customers. For example, the widgets may be customized based on the customer profile, i.e., the type of energy sources, the usage data, the customer's preferences as to the usage of electricity, the customer's monitored usage habits, energy consumption data of the community where the customer is located, and the like. A user can have different user accounts, and each account can have a different profile. Also, a meter may be inquired remotely to see if power is down at the meter and not inside a customer's home. Thus, one customer may have a plurality of customized profiles, from which a customer may select a profile to apply at any given time. Additionally, the customer may be able to manage or communicate with individual electrical devices and appliances in their home.

For example, these systems may include hardware, software, communications interfaces, consumer energy displays and controllers, customer-associated systems, Meter Data Management (MDM) software, supplier business systems, and the like. In one embodiment, the system may be hardware-based, software-based, or any combination thereof.

Individual customer profiles may also show usage/consumption data that closely matches the usage information that will be sent to the customer in a bill. The subject matter disclosed herein enables a framework that helps develop reusable and extendable widgets. The subject matter disclosed herein may also enable a replicable portal that allows the addition of widgets. In one embodiment, a customer may be a residential user. Optionally, the customer may be a commercial user. A network may be a wired network or a wireless network 160.

Also shown are two power customers, 170 and 172. Power customer 170 uses an extended reality headset to experience or view an immersive interactive energy assessment. Power customer 172 is shown using a smartphone to experience or view an immersive interactive energy assessment, as further described below. The customers may be guided by an energy auditor 156 that is in the same virtual space of the customer premises 102 space but geographically separate. The energy auditor 156 can be a person using extended reality headsets or other displays like a smartphone or computer. The energy auditor 156 guides customers 170 and 172 through the customer's premises 102 to conduct the immersive interactive energy assessment.

In another example, the energy auditor 156 is an avatar that is programmatically created to guide customers 170 and 172 through the customer's premises 102. Tools to create avatars are available for free and can be purchased on platforms such as GitHub and Crunchbase.

In general, customer premises 102 coupled to the power distribution system 120 are able to include any combination of residential, commercial, or industrial buildings.

### Immersive Environment

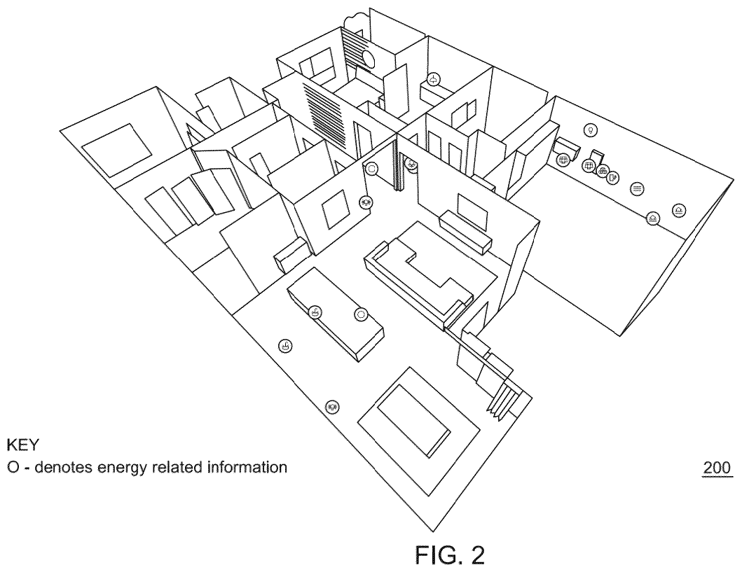

Now, in FIG. 2, image 200 shows a top-level view of a real-world residential space, according to an example. This image may be rendered to power customers 170 and 172, as shown in FIG. 1. This image 200 can be a real-world image, a virtual image, or a combination of both. Typically, image 200 is captured using a 3-D image from LiDAR, photogrammetry stitching, or the generation of a point cloud. Another example is accessing images in an infrared frequency range to identify differences in heat. The images may be captured by power customers 170 and 172 using cameras, such as smartphone cameras, or via a third-party system.

FIG. 2 portrays the concept of virtually exploring a digital twin of the customer's home, in which customers or auditors can see possible appliances, thermostats, and more are denoted in the virtual space. Customers using computers, smartphones, or extended reality headsets can move about the virtual space and visualize carbon efficiency scores related to items in the home. The carbon efficiency scores are based on disaggregated energy data mixed with imagery and captured characteristics.

This perspective view is a collection of computer-generated indicators (shown in circles with different graphics inside) of specific energy information. These computer-generated indicators are generated by identifying objects in the image 200 related to energy consumption, including appliances, HVAC, windows, range hoods, thermostats, doors, structural features, ceilings, HVAC vents, pool pumps, sprinkler pumps, switches, lights, or combinations. The objects identified can be identified based on receiving input from a user labeling the object related to energy consumption in the image. The user input can be text, voice, speech-to-text recognition, or a combination thereof. In another example, image recognition of the object related to energy consumption in the image is performed using one or more of Google Lens, Microsoft Lens, Greenshot, TinEye, and others, which are examples of image recognition technology. This will also be discussed further below in the section entitled “Overall Flow Diagram of Immersive Energy Assessment”. Further, the consumer may be given awards or incentives to label objects related to energy consumption.

These identified objects are used to access corresponding specific energy information. The specific energy information can be accessed from smart electric meters, appliances, smart home equipment, IoT equipment, smart thermostats, smart speakers, in-line watt meters, and more.

The computer-generated indicators (shown as circles with different graphics inside) are positioned within the image 200 to create a virtual reality image or mixed reality image by combining i) at least one computer-generated indicator of specific energy information near each identified object related to energy consumption of the identified object with ii) the image of the real-world space.

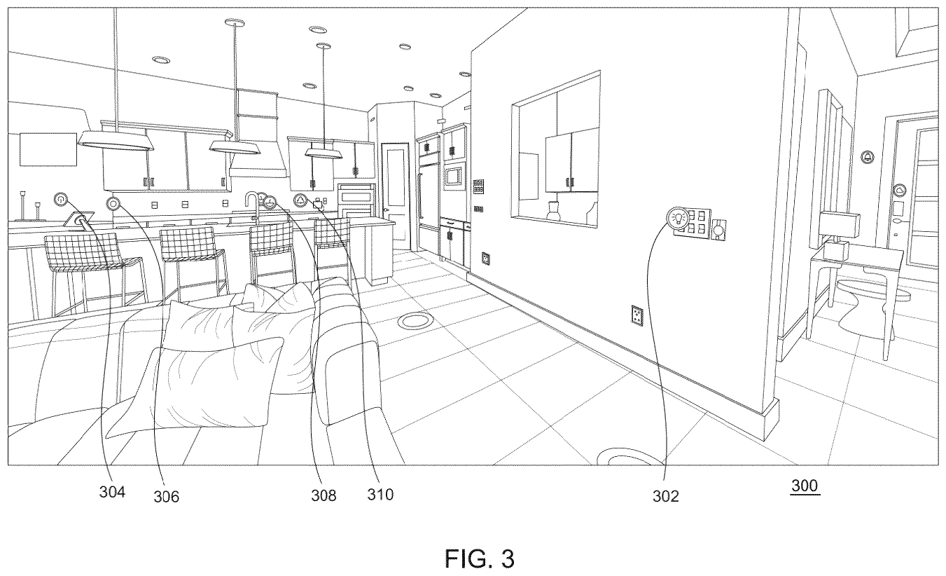

FIG. 3 is an image 300 of a more detailed view of a kitchen area in FIG. 2, according to an example. Image 300 illustrates the identified objects with the computer-generated indicators (shown as circles with different graphics inside, such as such as 302, 304, 306, 308, and 310) in the virtual reality image.

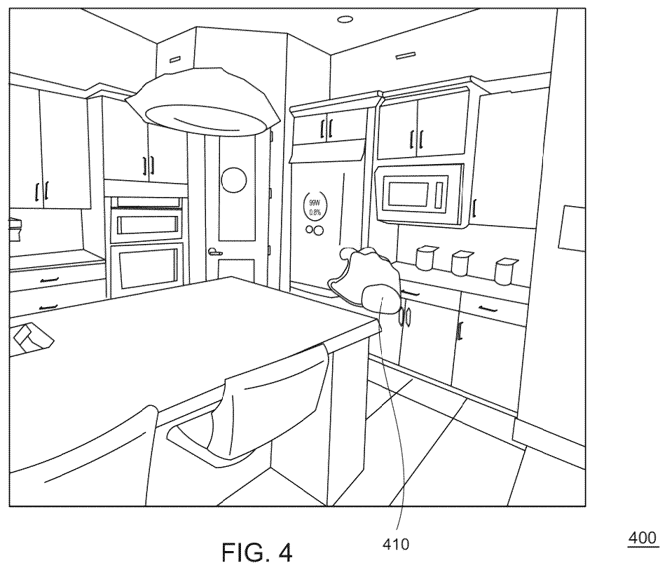

FIG. 4 is another image 400 of the kitchen area in FIG. 3 illustrating an identified object as a refrigerator, according to an example. Shown is a computer-generated hand 410, i.e., a user selection in the process of selecting a computer-generated indicator of specific energy information. Illustrated in FIG. 4 in response to the user selection of the computer-generated indicator is a presentation of the specific energy information corresponding to the identified object, i.e., the refrigerator, related to energy consumption. The real-time amount of wattage being consumed, i.e., 99 Watts, and the percentage of the real-time household energy consumption, i.e., 0.8%, is shown. In this example, the specific energy information corresponding to the identified object, i.e., the refrigerator, is overlaid on the identified object within the real-world image of the real-world space, creating another synthetic image.

In addition to the specific energy information being displayed, in another example, generic energy information from a manufacturer of the identified object related to energy consumption is displayed (Not shown).

Also, in lieu of, or in addition to, information from other parties, such as government websites, consumer reporting agencies, and third party tests agencies, regarding energy consumption for a model or specific type of the identified object can be displayed.

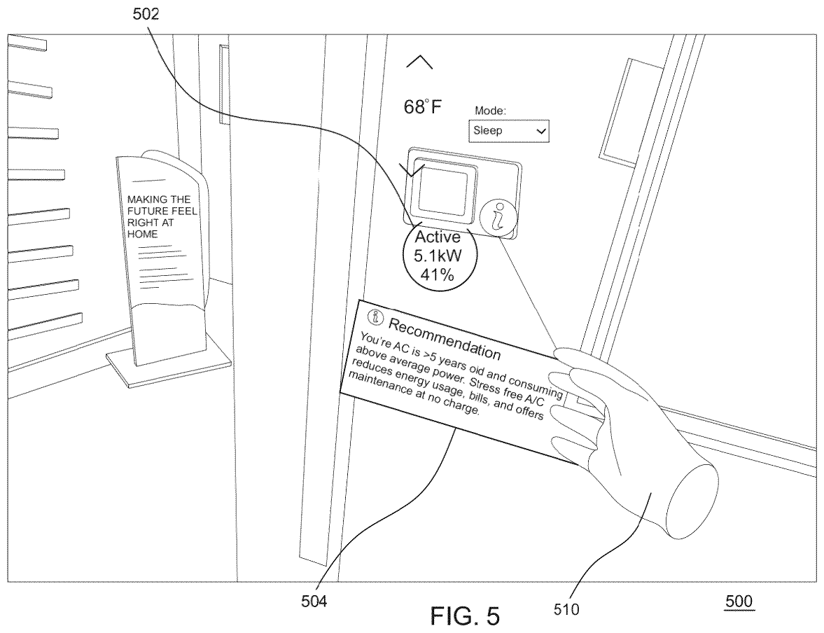

FIG. 5 is an image 500 of a hallway area in FIG. 2, illustrating an identified object as an HVAC thermostat, according to an example. In response to the user selecting a computer-generated indicator that was displayed near the thermostat, the real-time amount of wattage being consumed 502, i.e., 5.1 kWatts, and the percentage of the real-time household energy consumption, i.e., 41%.

In addition, a recommendation 504 is shown. Here, the recommendation includes “Your AC is >5 Years old and consuming above-average power.” The recommendation continues with a specific service “Stress-Free AC reduced energy usage, bills, and offers maintenance at no charge.” In this example, the recommendation corresponding to the identified object, i.e., thermostat, includes creating another synthetic image by combining the specific energy information with the real-world image of the real-world space.

In one example, the recommendation is presented automatically with specific energy information. In another example, an additional computer-generated indicator, such as the “i” for “Information,” is presented. Once the user selects this “i” in the virtual environment, the recommendation 504 is presented for improving energy efficiency.

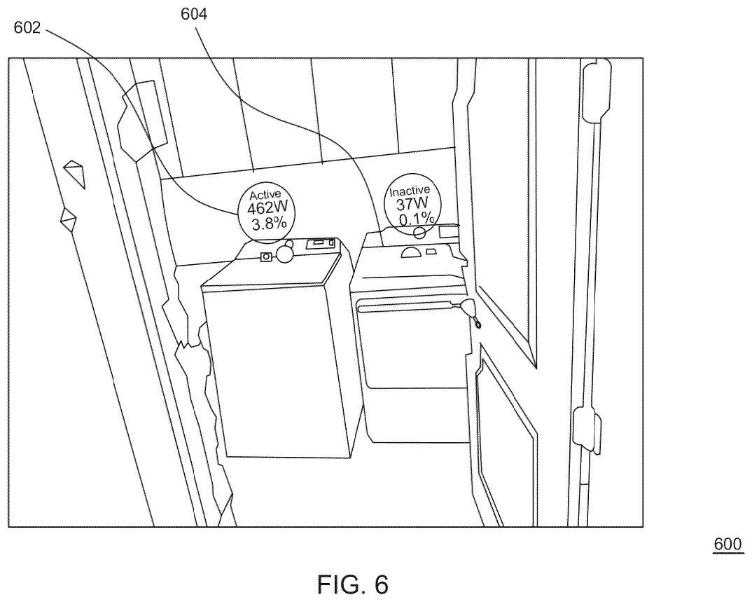

FIG. 6 is an image 600 of a laundry room area in FIG. 2 illustrating the identified object as a clothes washer and dryer, according to an example. Shown here are the real-time amount of wattage 602, 604 being consumed, i.e., 462 Watts, and the percentage of the real-time household energy consumption, i.e., 3.8% for the electric dryer and 37 W and 0.1% for the washer.

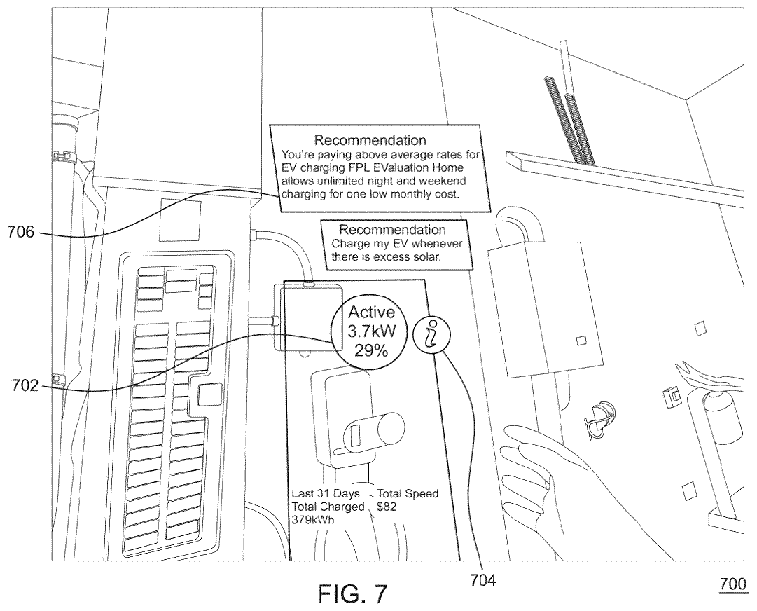

FIG. 7 is an image 700 of a garage area from FIG. 2 illustrating the identified object as an electric vehicle (EV) charger, according to an example. Shown here are the real-time amount of wattage 702 being consumed, i.e., 3.7 kWatts, and the percentage of the real-time household energy consumption, i.e., 29%. The image 700 also has the specific historical energy information for the identified object being displayed, e.g., total charged over the last 31 days was 379 kWatts at the cost of $82.

Also shown in FIG. 7 is the “i” additional information indicator 704 with the recommendations 706 that are displayed upon the user interacting with the “i” indicator. Here, the recommendation states, “You are paying above average rates for EV charging. FPL Evolution Home allows unlimited night and weekend charging for one low monthly cost.” There is another recommendation “Charge my EV whenever there is excess solar.”

Other additional information may include presenting the recommendation for improving energy savings, including one of tinting windows, turning off fans or lights in an empty real-world space, replacing lightbulbs, identifying air leaks around windows, doors, vents, through ceilings, and more.

The additional information may include overlaying a photorealistic image of a replacement object on the real-world image, such as tinting on windows.

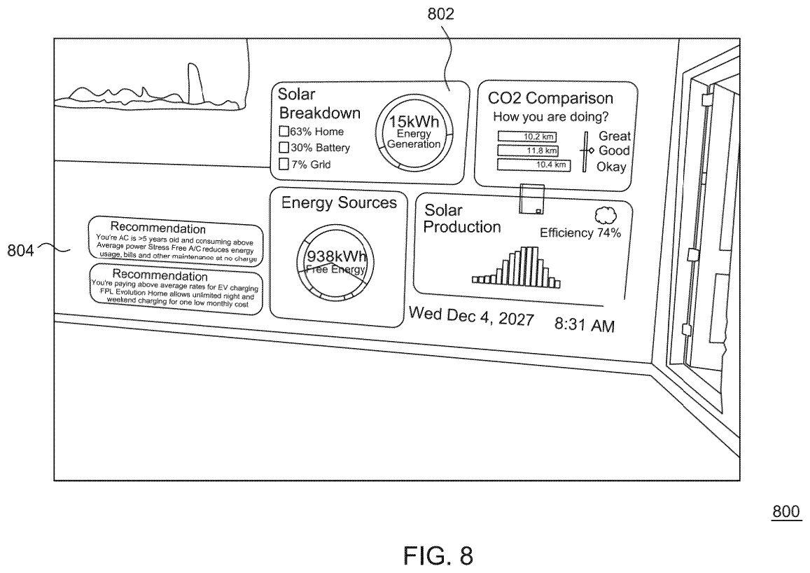

FIG. 8 is an image 800 of general information displayed in an open area in FIG. 2, according to an example. This displays more general information for photovoltaic solar and a backup battery shown in an open space of the real-world space, such as a garage wall. Shown here is the solar breakdown 802 of how much of the solar is being consumed by the home, 63%, stored in the battery, 30%, and sent back to the grid, 7%. Other information includes solar production, CO2 comparison, energy sources, and along with recommendations 804.

### Overall Flow Diagram of Immersive Energy Assessment

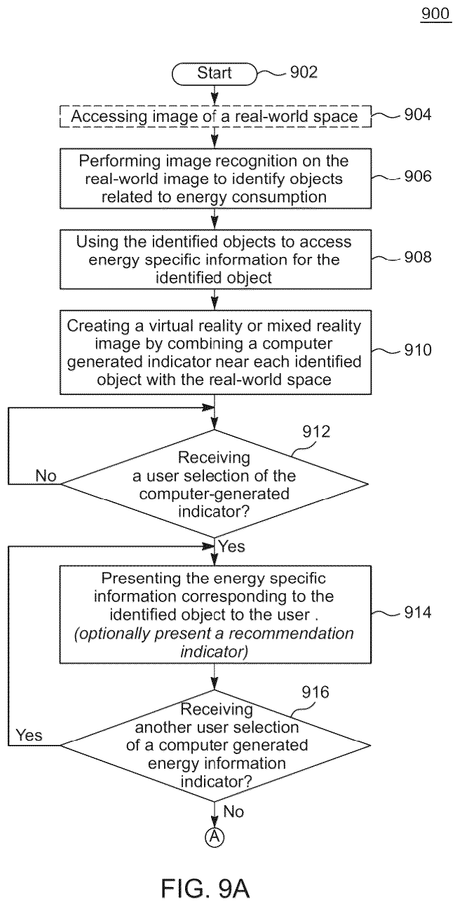

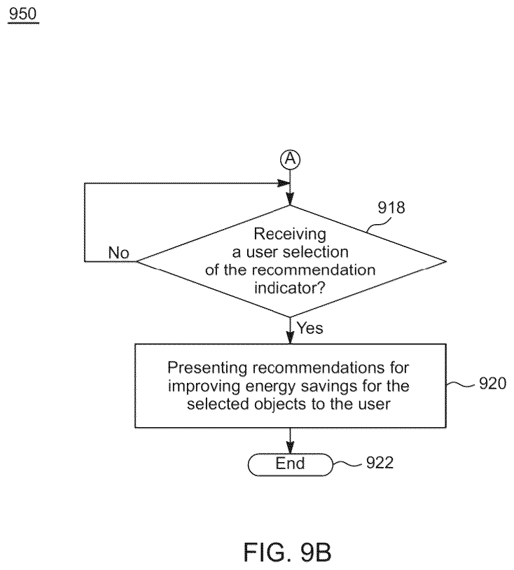

Referring now to the flow diagram 900 and 950 in FIG. 9A and FIG. 9B, the present invention uses extended reality techniques to capture real-world images of a real-world space, according to an example. The process begins in step 902 and immediately proceeds to step 904 to access an image of real-world space. In one example, the image capture is two-dimensional, and in other examples, the image capture uses LiDAR, photogrammetry stitching, or other methods for determining ranges through the generation of a point cloud, such as with Pix4d.com software. These images may be captured with a smartphone, extended reality headset, or with cameras.

Moreover, image capture can include non-visible wavelengths of light, including infrared, to assist with the detection of heat loss and sources of heat generation. The process continues to step 906.

Next, in step 906, image recognition is performed to identify objects related to energy consumption. These objects can include appliances, HVAC, windows, range hoods, thermostats, doors, and other structural features, such as ceiling type, HVAC vents, pool pumps, and sprinkler pumps. Examples of image recognition are Google Lens, Bixby Vision, Huawei Hi Vision, and others. The location for each identified object, i.e., these objects' x,y,z coordinates in the real-world image, is also stored. The process continues to step 908.

Next, in step 908, for objects that have been identified as related to energy, specific energy information is gathered from different sources. The information can be accessed from one of a smart electric meter, an appliance, smart home equipment, IoT equipment, smart thermostats, smart speakers, in-line watt meters, home energy monitor equipment, such as those available from Sense.com or any combination thereof. The system could also instruct the user to turn on or off certain items in their house to better quantify energy consumed by a targeted appliance. Optionally, geographic location, weather, and orientation of a real-world space with respect to the sun may also influence the specific energy information. The energy consumption from non-renewable energy sources defines a carbon footprint for real-world space.

In one example, a smart meter combined with AI analyzes the power consumption at a customer's location to categorize consumption by load/appliance. The consumption may be real-time or historic. An extended reality device can be used to visually recognize a load/appliance category on the premises using a different AI process. Then, the smart meter data categorization is automatically selected for the recognized load/appliance based on the visually determined AI category that matches the smart meter AI-determined category.

Optionally, generic energy-related information may also be accessed. This generic energy information may be accessed from the manufacturer and information from third parties regarding energy consumption for a model, e.g., Energy Star information. The process continues to step 910.

Next, in step 910, for objects that have been identified as related to energy, a computer-generated indicator is generated and positioned near each of the objects to denote that specific energy-related information is available. A synthetic image, i.e., virtual reality or mixed reality image, is created by generating and positioning the computer-generated indicators near each identified object in the real-world space. In one example, the 3D rendering of the real-world image, i.e., physical space, e.g., the residence of a user or a commercial property of a user, allows users to pan through the real-world space and easily identify where an energy consuming object is based on the computer-generated indicators located throughout their real-world space. Panning can be accomplished through a variety of platforms, including a web or cellphone app (manual panning/paging) or through immersive virtual rendering available for use with an extended reality headset. The process continues to step 912 once a user selection of a computer-generated indicator is received; otherwise, if no selection is received, the process loops back to start step 912 as shown.

In response to receiving a user selection of the computer-generated indicator in step 912, in step 914, the system presents the specific energy-related information corresponding to the identified object to the user. Optionally, generic energy information or energy consumption information may also be presented. Further, a recommendation indicator may also be presented, i.e., a computer-generated recommendation indicator that a user could select and be presented with a recommendation for improving energy savings for the corresponding identified object. The specific energy information and/or the computer indicator is presented using extended reality techniques, such as augmented reality. The process continues to step 916.

In step 916, if another user selection of another computer-generated indicator is received, the process loops back to step 914, as shown. Otherwise, the process continues to step 918.

In response to receiving a user selection of the computer-generated indicator, the energy-specific information is presented. Optionally in step 918, the system presents the recommendation for improving energy savings for the corresponding object to the user in step 920 and completes the flow in step 922. The recommendation may be putting tinting on windows, placing foliage outside, turning off fans or lights running in an empty real-world space, replacing incandescent lights with LED lights, and identifying air leaks around windows, doors, vents, and through ceilings.

In one example, AI-assisted recommendations for strategies and solutions to improve energy consumption and carbon/inefficiency-score throughout real-world space are provided. Further, recommendations can be selected and placed in a virtual “basket”, like a virtual shopping cart, that can be used to request follow-up sales/service calls to be addressed by technicians/associates or affiliates.

In another example, the system overlays a photorealistic representation of the recommendation in the real-world space. For example, window tinting may be applied over the real-world image of the window. Outside foliage is recommended and presented. Image effects of photography/videography, such as lighting, color, luminesce, reflectance, etc., may be applied. Further, the window's orientation versus the sun may be determined by many means, including metadata, GPS from the image, light patterns through the window, and user input.

Another example is replacing a current washer and dryer with an energy-efficient washer and dryer. The system may overlay a photorealistic image of the replacement washer and dryer to give the user an understanding of how the end results may look. In addition, recommendations on where to purchase the replacement appliance and recommendations for installation may also be included.

In another example, the user may turn on/off an identified object related to energy consumption, such as the washer and dryer. This may help to understand the amount of energy used in real-time when disaggregating energy consumption from a smart meter. The identified object is controlled as an IoT device. Another example is a smart thermostat, such as a Next thermostat, which is an IoT device that can be remotely controlled over the Internet, not just turned on or off but set to a specific temperature to measure heating or cooling energy consumption.

This ability to turn on/off the identified object related to energy if it does not connect as an IoT device could be simulated based on the manufacturer's specification and whether age or condition (e.g., age or condition of an AC unit) needs to be taken into account for efficiency. This energy information is presented to the user.

The overlaying of photorealistic images includes inserting the replacement washer and dryer with image editing software that uses a resizing transformation to be consistent with the real-world image.

Optionally, coupons, discounts, partnerships, and energy rebates can be presented along with the recommendations.

Budgets may also be set so that recommendations are ranked in terms of the highest energy savings for the lowest cost to stay within a consumer's budget. Stated differently, potential energy savings, carbon/energy inefficiency, and energy recommendations can be optimized for budgets. With all available carbon/energy inefficiency recommendations, customers can experiment with the best allocation of their investment by allowing them to enter their budget and automatically calculate the best places to invest in optimizing carbon/efficiency. Further, a what-if tool allows the user to evaluate the optimum carbon/energy efficiency improvements for any given disposable budget and estimated energy bill savings.

The goal to reduce energy consumption and reduce carbon footprint can be “gamified” to allow consumers to publish their carbon/efficiency score on social media or in the virtual space they use to interact with friends and family (i.e., Facebook, Instagram, Tiktok, Roblox. Sandbox.com and more) with before/after story-lines.

### Flow Diagram of Object Related to Energy Consumption

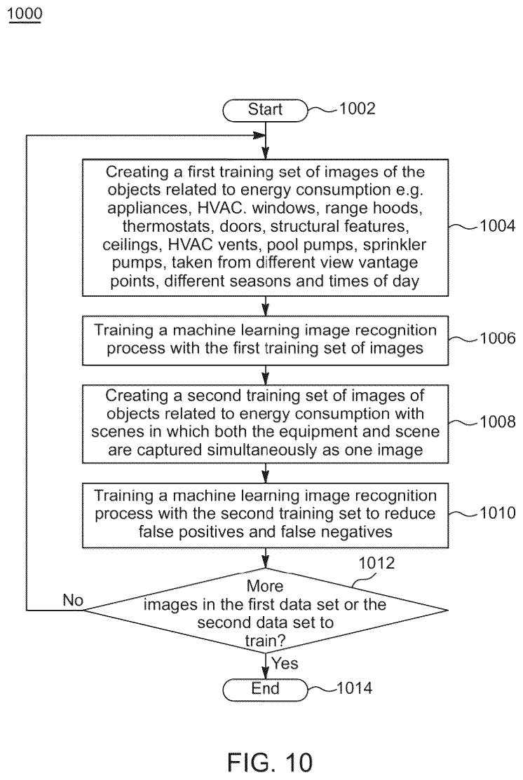

Turning to FIG. 10, a process flow 1000 of machine learning image training set creation is depicted, according to an example. The process begins in step 1002 and immediately proceeds to step 1004.

In step 1004, a first training set of images of the objects related to energy consumption is created, e.g., appliances, HVAC, windows, range hoods, thermostats, doors, structural features, ceilings, HVAC vents, pool pumps, and sprinkler pumps. These images are taken from different viewpoints, seasons, and times of day. The process continues to step 1006.

In step 1006, the machine learning image recognition process is trained with the first training set of images. The process proceeds to step 1008.

In step 1008, a second training set is created of images with objects related to energy consumption with scenes in which both the equipment and surrounding scenes are captured simultaneously as one image. The process continues to step 1010.

In step 1010, the matching learning image recognition process is trained with the second training set to reduce false positives and false negatives. The process continues to step 1012.

Step 1012 is a test to determine if there are more images in the first training set or the second training set for training. If there are more images to train, the process returns to step 1004 as shown. Otherwise, the process terminates in step 1014.

### Flow Diagram of Object Related to Energy Consumption

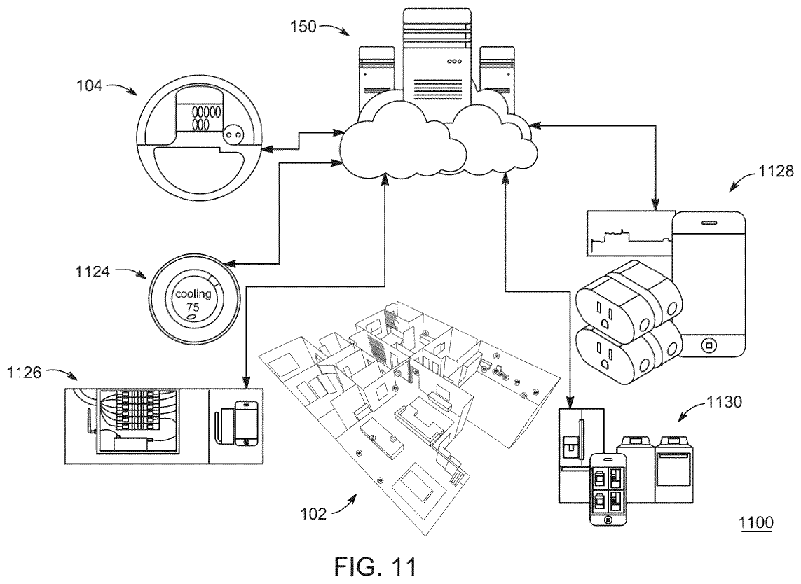

Turning now to FIG. 11, a block diagram 1100 of various methods of accessing specific energy information from an object related to energy consumption, according to an example, is depicted. Customer premises 102, smart electric meter 104, and cloud computing platform 150 have been previously described above with reference to FIG. 1.

In addition to the smart electric meter 104, the other methods to access specific energy information for an identified object related to energy consumption include smart appliances 1130, such as a washer, a dryer, and a refrigerator, which report their real-time or current energy usage. Also shown are smart plugs 1128 from Emporia Corps of Littleton Colorado, which monitor the energy usage of an object plugged into it.

A smart thermostat 1124, such as Google's Nest or others, can report energy consumption from an HVAC system or systems. Home energy monitors 1126, such as those available from Sense Labs, Inc. of Cambridge, Massachusetts, and others can report energy usage for a specific object in a household.

Devices that monitor energy usage, as shown in FIG. 11, can communicate back to the cloud computing site 150 of FIG. 1 using the public/private network 140 through a wireless connection 160 or both.

### Management of a Portfolio of Properties

The shortage of available energy auditors is an industry-wide issue. Many residential and commercial property owners hire energy auditors directly, especially for commercial properties. Additionally, owners of multiple properties often lack the tools needed to gain the deep insights necessary for effective energy management strategies.

This example expands the initially outlined process for residential applications to cover commercial and industrial properties as well, including the ability to identify trends across multiple premises.

Leveraging extended reality, 3D building models, and advanced analytics, this example provides portfolio-level energy insights that are especially valuable for owners and operators managing multiple commercial buildings.

This example enables commercial customers to reduce energy consumption and costs. Current energy auditors face scalability limitations and lack the depth of insight needed for effective energy management strategies.

Aggregated data from multiple commercial properties, such as building scans, smart meter data, and more-allows for portfolio-wide energy analytics, centralized energy management, and custom solutions tailored for commercial clients.

Key benefits of this example include energy and cost savings for commercial building owners and operators. Additionally, it supports improved sustainability and reduces environmental impact. This solution may be offered as a standalone product or service to enhance operational improvements.

This example provides energy audits in extended reality and expands these capabilities to portfolios of properties. A virtual representation of physical spaces is created, overlaid with virtualized energy efficiency scores for major appliances, windows, doors, and other structural features. The areas impacting carbon and energy efficiency are identified. Layering multiple renderings allows the identification of portfolio-level trends for clients managing multiple properties.

Each property's digital twin is a life-like, interactive 3D model that reflects building structures, appliances, and infrastructure, with real-time overlays highlighting energy usage. Color-coded heat maps visualize energy consumption across zones, and users can navigate the digital twin using VR controllers, headsets, or other interfaces to explore different rooms or building elements. By clicking on components like appliances, specific data, including energy efficiency ratings and historical usage is displayed for the users.

The use of alerts and notifications enhances situational awareness with visual cues such as flashing icons or highlighted zones within the digital twin, alerting users to issues (e.g., a malfunctioning HVAC system displayed in red). Detailed pop-ups provide further context and recommended actions, while real-time updates ensure the latest information is always available.

Energy usage is illustrated with heat maps where areas glow according to consumption, e.g., with red for high use and blue for low. The use of heat maps enhances system and component highlighting. Additional data layers, such as temperature and appliance performance, reveal interrelated factors affecting efficiency, while each component, like a window or HVAC system, displays its energy rating and recent performance metrics.

The maintenance history is presented on a scrollable, interactive timeline, showing previous repairs, inspections, and performance data. Users can click on timeline entries for detailed logs, including technician notes and parts replaced, while predictive maintenance flags upcoming needs based on analytics, supporting proactive scheduling.

Through metrics and analytical insights, the system provides in-depth analytics panels to monitor energy efficiency trends, cost savings, and equipment performance. AI-driven insights suggest optimizations, such as thermostat adjustments based on forecasted weather. Users can simulate “what-if” scenarios to visualize impacts, like potential savings from energy-efficient lighting, and generate professional reports complete with graphs, charts, and tables for stakeholder presentations or compliance documentation.

Finally, the platform integrates user-friendly immersion features with VR and AR modes. In VR, users enter a virtual control room, interacting with holographic digital twins through hand gestures, while in AR, tablets or AR glasses overlay data and digital elements onto physical spaces for on-site reviews. Spatial sound and haptics enhance the experience, directing attention to needed areas through sound cues or tactile feedback for urgent alerts, adding an extra sensory layer to the immersive system.

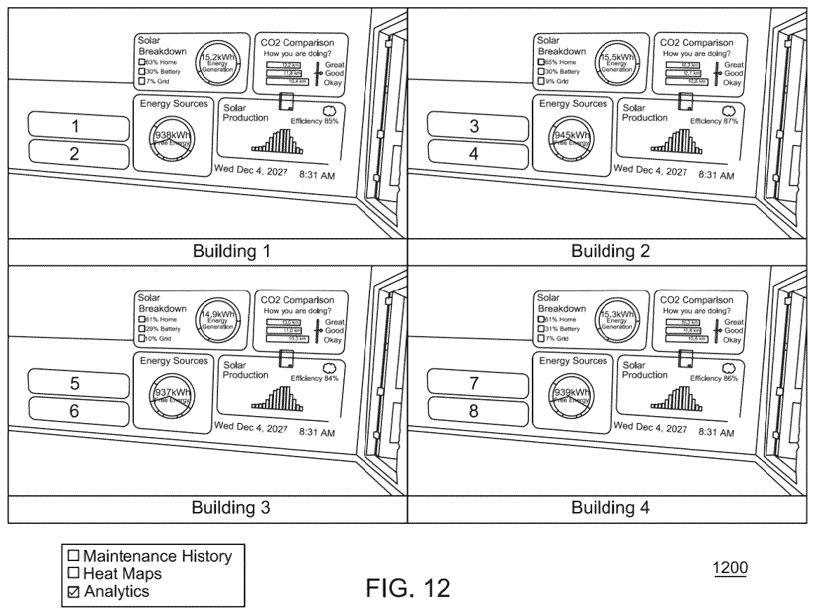

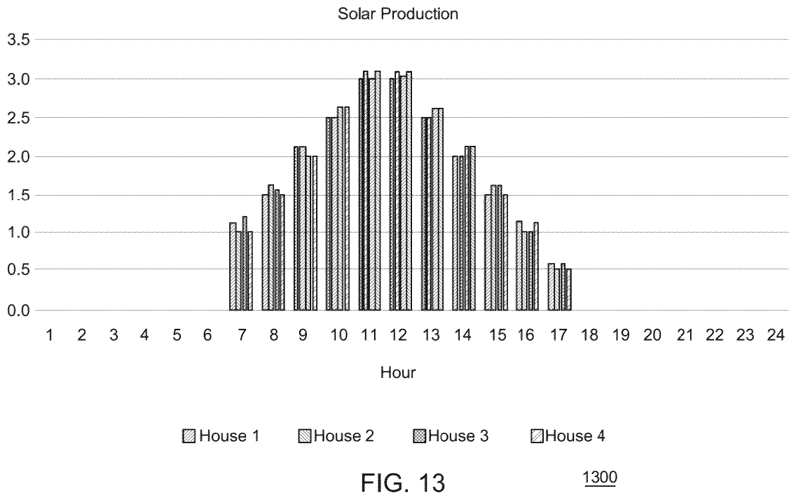

FIG. 12 is a display 1200 of four properties in a portfolio compared side-by-side, according to an example. FIG. 13 is a display 1300 of solar production for four properties over time, according to an example. In these two example displays, the centralized dashboard spans multiple high-resolution screens or VR headsets, immersing users in a virtual control room. A central interface displays 3D digital twins of properties within the portfolio, which orbit around a central data hub with dynamic, real-time widgets showing metrics like energy consumption, cost savings, and carbon footprint. These interactive widgets allow users to zoom in or click for detailed data, while a drag-and-drop customization feature personalizes the layout and prioritizes key metrics.

### Targeted Customer Engagement in Energy Management

This example addresses the shift in communications and messaging from being a preference to becoming an expectation. In today's digital landscape, residential and business customers alike demand highly personalized and relevant messaging that aligns with their unique needs and interests. This shift reflects a significant opportunity for companies to increase engagement, enhance customer understanding, and build loyalty. According to Hubspot, marketers who implement segmented and targeted campaigns see revenue boosts of up to 760%.

Achieving this level of personalization requires precise segmentation, effective targeting, and robust customer profiles. However, traditional approaches often rely on basic data, such as geography or demographics, which fail to capture the complex and individualized characteristics of each customer's environment. The real challenge lies in gathering a more comprehensive data set that supports truly personalized interactions and improves campaign effectiveness. Existing solutions primarily use customer relationship management (CRM) systems and analytics tools for basic segmentation, but this often results in generic messaging due to insufficient customer information. Current utility industry solutions sometimes incorporate psychographics, such as environmental motivations or electric vehicle ownership, but segmentation often remains broad and fails to account for unique user characteristics.

The innovative approach in this example incorporates 3D home scans, captured through lidar or photogrammetry, combined with smart meter data to create highly detailed home energy profiles. By employing advanced object detection to identify household items and linking these insights with energy usage patterns, utilities can develop dynamic customer personas based on real consumption data. This approach significantly surpasses traditional segmentation by providing utilities with actionable insights and supporting personalized recommendations. Integrating this solution into an energy management platform could enhance customer satisfaction, drive engagement, and improve operational efficiency through precise targeting of energy-saving recommendations and relevant products or services.

Furthermore, this example's capability to visualize potential changes within a customer's 3D home space aids in decision-making for upgrades or new services, likely increasing customer engagement and satisfaction. The benefits extend to potential partnerships, where outside retailers and service providers could access this rich data for a fee, creating an additional revenue stream.

This example allows for tailored messaging strategies for specific customer segments, such as tech enthusiasts versus traditionalists, energy “guzzlers” versus eco-conscious users, and multi-generational households versus empty nesters. For instance, marketplace promotions can be tailored based on content engagement, such as offering smart thermostats to customers who read relevant articles or electric vehicle chargers to those watching EV-related videos. Messaging can also be customized for residential or business customers based on size and specific needs, like targeting LED lightbulbs for renters or HVAC systems for homeowners.

Additionally, messaging can be adjusted for motivations, with money-saving tips for cost-conscious customers and carbon footprint reduction suggestions for environmentally aware users. Income-based messaging enables utilities to reach eligible households with relevant programs and financial assistance. This innovation provides a new revenue generation avenue by selling or licensing this technology to third parties, while also allowing utilities to collect deeper insights into customer needs and behaviors.

This example builds upon a previously established extended reality (XR) energy audit tool, enhancing its capabilities by integrating detailed 3D home scans obtained via lidar or photogrammetry with smart meter data to create dynamic and detailed home energy profiles. These profiles are then used to generate highly personalized energy consumption recommendations and targeted marketing strategies. The process involves using advanced object detection techniques to identify and classify items within the home, which, combined with energy usage data, allows for creating segmented customer personas based on actual energy consumption patterns and living conditions. This example significantly improves upon existing segmentation techniques by providing utilities with actionable insights derived from a deep understanding of individual customer environments. This example can be implemented through integration into an existing suite of energy management tools, offering it as an advanced service option to residential customers within their utility network. The service enhances customer satisfaction through personalized engagement and drives operational efficiencies by enabling more precise targeting of energy-saving recommendations and related products or services.

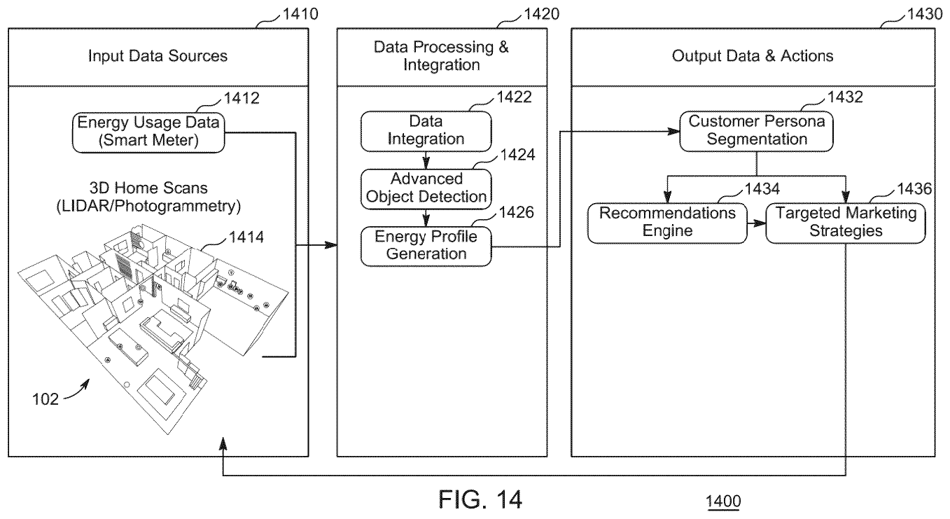

FIG. 14 is a functional block diagram 1400 for providing advertisements in an immersive interactive environment, according to an example. The system consists of three main modules: Input Data Sources 1410, Data Processing and Integration 1420, and Output Data and Actions 1430. The Input Data Sources 1410 module gathers critical information through two components. The 3D Home Scans (Lidar/Photogrammetry) 1414 retrieve detailed 3D scans of customer homes using advanced lidar and photogrammetry technologies, while the Energy Usage Data 1412 collects real-time energy consumption data from smart meters.

The Data Processing and Integration module 1420 processes this information through three interconnected components. The Data Integration Module 1422 aggregates and synchronizes data from 3D scans and smart meters. This integrated dataset is then analyzed by the Advanced Object Detection 1424 component, which identifies and segments objects within the home. Finally, the Energy Profile Generation 1426 component combines object detection and energy usage insights to create dynamic and detailed energy profiles for each home.

The Output Data and Actions module 1430 uses these energy profiles to drive actionable outcomes. The Customer Persona Segmentation 1432 component segments customers based on their energy consumption patterns and living conditions. Using these personas, Recommendations Engine 1434 provides personalized energy-saving tips and product recommendations tailored to each customer. Lastly, the Targeted Marketing Strategies 1436 component generates customized marketing messages for different customer segments, aligning recommendations with customer needs and behaviors. This comprehensive system enables precise data-driven insights and engagement strategies.

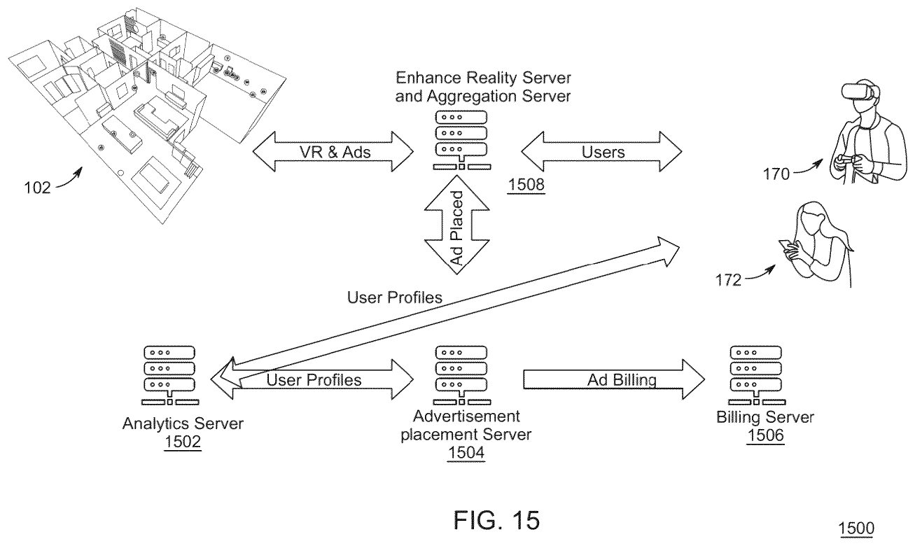

FIG. 15 is a functional block diagram 1500 for providing advertisements in an immersive interactive energy environment, according to an example. Shown is the customer premises 102 as part of an immersive environment and two power customers 170, 172 as described previously. The power customers 170, 172 are the individuals interacting in the immersive environment.

Analytics server 1502 gathers user engagement data and tracking interactions, which feed into subsequent processes for advertisement placement with a user browsing or user app activity, where user interactions are first captured. Power customer profiles are stored in an analytics server 1502. The power customer profiles are detailed information on each user. User profiles could include demographic details, preferences, and behavior patterns, enabling the system to tailor advertisements to individual needs and increase relevance. This server plays a key role in collecting, processing, and analyzing data related to user engagement and content preferences. The analytics server 1502 could also aggregate data from multiple sources, including social media and public and private databases, to provide insights or enable real-time enhancements in advertisement placement, especially in virtual or augmented reality environments.

Advertisement placement server 1504 uses the power customer profiles to select the most relevant advertisement. The advertisement placement server 1504 also receives information about identified objects related to energy consumption, with which the power customers 170 and 172 interact. The user profiles are matched against advertisement content. At this filtering stage, two possible outcomes arise: if the advertisement meets the user's preferences, the advertisement is selected and sent to the enhanced reality server and aggregations server 1508, where the advertisement is shown to the user 170, 172. Alternatively, if the advertisements do not meet the criteria, they are blocked and prevented from reaching the power customers 170, 172.

For example, the power customer 170 interacts with a thermostat, as shown in FIG. 5. This thermostat may not be a smart thermostat. An advertisement for smart thermostats, air filters, AC, or heating turn-up services may be selected in this example. Likewise, if power customer 172 interacts with a solar converter to review solar production in FIG. 8, an advertisement may be selected for washing solar panels.

The enhanced reality server and aggregation server combine the selected advertisements into the virtual reality space 102 and present it to the power customers 170, 172. This block represents the integration of advertisements within a virtual reality environment, where advertisements are placed and displayed to users. The VR setting can create immersive advertisement experiences, engaging users in unique ways that align with virtual content.

The billing server 1506 manages the financial transactions associated with advertisement placements. It could track advertisement spending, handle billing cycles, and manage payments between advertisers and the service provider.

The flow for this example is similar to the flow in FIG. 9. There is an additional substep in step 914. This substep is where a relevant advertisement and a recommendation are presented to the user, according to FIG. 15.

### See It, Control It Platform

This example presents a comprehensive solution to the challenge of inefficient residential energy management by integrating energy usage insights with direct control over consumption sources. Unlike traditional approaches, which typically focus on either data analytics or smart home control, this platform bridges the gap, enabling users to both visualize energy consumption and directly control devices through a single, cohesive interface.

Currently, data analytics tools offer valuable insights into energy usage patterns, including trend analysis and predictions, but they lack the ability to directly influence energy consumption. Users can identify where energy is being wasted but are often unable to make immediate adjustments to improve efficiency. Conversely, smart home control systems allow users to manage lighting, heating, and appliances, often through automation and voice integration. However, these systems typically lack the detailed analytics needed to fully understand the impact of these controls on overall energy usage, making it difficult for users to achieve optimal energy efficiency.

The “See It, Control It” platform addresses these limitations by integrating 3D visualization, advanced analytics, and IoT control into a single solution. The platform scans and renders a 3D model of the home, mapping out appliances and devices, while robust analytics provide insights into energy usage patterns based on smart meter data. This integration allows users to visually pinpoint inefficiencies and take immediate action, adjusting settings, schedules, and device usage directly through the interface. By combining 3D scanning, computer vision, and IoT technology, the platform delivers a unified residential energy management system.

Key benefits include:
1. Unified Visibility and Control: Users gain both visibility into their energy usage and the ability to adjust it through IoT control in a single, intuitive interface.
2. Closed-Loop System: Users can act on energy-saving insights immediately, creating a feedback loop for continuous optimization.
3. Open Ecosystem for Integration: The platform supports third-party integrations, enabling the expansion of capabilities through an open API.

This example provides seamless integration of disparate technologies and allows users unprecedented insight and control over their energy consumption, creating a one-of-a-kind residential energy optimization tool. Further, this example enhances customer control, satisfaction, and transparency, potentially reducing energy audit calls. Furthermore, the system is compatible with demand-side management (DSM) programs, enabling customers to see their contribution to energy savings in their communities.

Additional benefits of this platform include cost savings, AI-driven recommendations, strong data privacy, and a flexible, open ecosystem. By enabling third-party integrations, the platform can expand into related services such as solar energy management, EV charging, and personalized generative AI recommendations, offering a future-ready solution for residential and potentially commercial energy management.

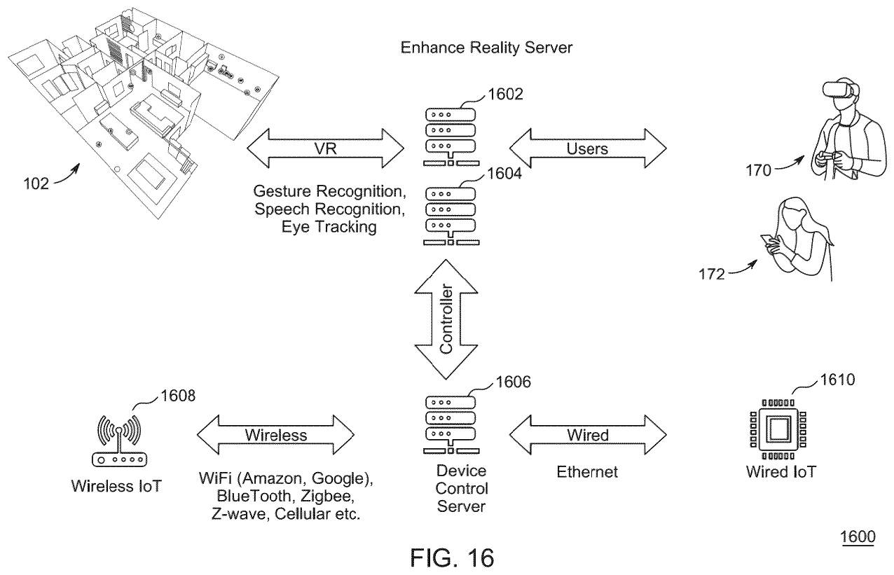

FIG. 16 is a functional block diagram 1600 for controlling a device in an immersive interactive environment, according to an example. This solution offers a unified platform that addresses the inefficiencies of residential energy management by integrating energy usage insights with real-time control over energy-consuming devices. The “Say It, Control It” platform outlines a system that integrates various technologies for immersive user interaction and control. Key components include power customers 170, 172. The Enhanced Reality Server 1602 supports VR environments and is communicatively coupled with Gesture Recognition, Speech Recognition, and Eye Tracking Server 1604. The server 1604 accepts various forms of user input, such as gesture recognition, speech recognition, and eye tracking, allowing users to interact with and control devices intuitively.

The Device Control Server 1606 is communicatively coupled to the gesture recognition, speech recognition, and eye tracking server 1604. The server 1606 receives user input from server 1604 and manages connected wireless devices 1608 and wired devices 1610. Server 1606 handles communication with devices 1608 and 1610 via different connectivity methods, both wired and wireless. Supported wireless protocols include WiFi, Bluetooth, Zigbee, Z-Wave, and cellular, as well as wired options like Ethernet. The server 1606 connects to a range of IoT devices, allowing seamless control over home or office devices. This system 1600 provides a seamless, responsive environment where power customers 170, 172 or other users can control devices through natural inputs in an enhanced reality setting.

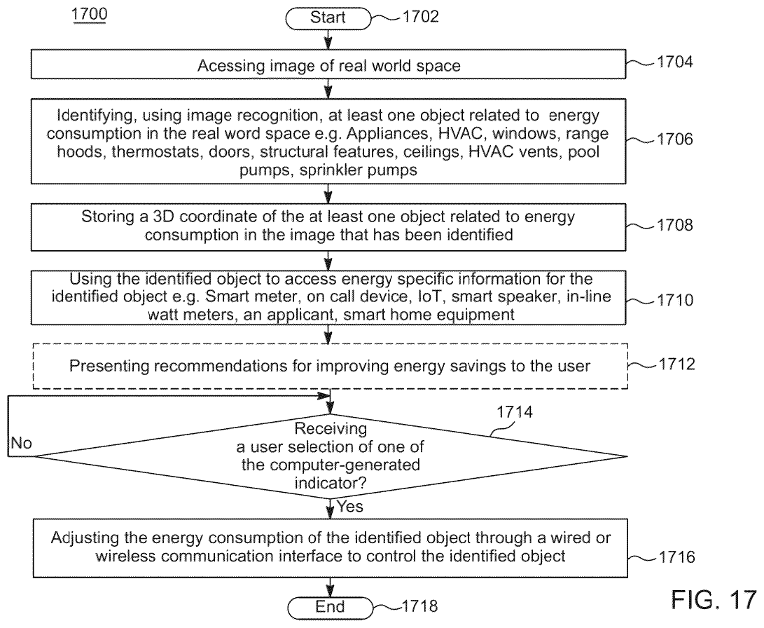

FIG. 17 illustrates a process flow 1700 for controlling a device in an immersive interactive energy environment 102, according to an example. The present invention uses augmented reality techniques to capture real-world images of a real-world space. The process begins in step 1702 and immediately proceeds to step 1704 to access real-world space. In one example, the image capture is two-dimensional. In other examples, the image capture uses LiDAR, photogrammetry stitching, or other methods for determining ranges through the generation of a point cloud, such as with Pix4d.com software. These images may be captured with a smartphone, VR headset, or with cameras.

Moreover, image capture can include non-visible wavelengths of light, including infrared, to assist with the detection of heat loss and sources of heat generation. The process continues to step 1706.

Next, in step 1706, image recognition is performed to identify objects related to energy consumption. These objects can include appliances, HVAC, windows, range hoods, thermostats, doors, other structural features, ceiling types, HVAC vents, pool pumps, and sprinkler pumps. Examples of image recognition are Google Lens, Bixby Vision, Huawei Hi Vision, and others. The location for each identified object, i.e., these objects' x,y,z coordinates in the real-world image, is also stored. The process continues to step 1708.

Next, in step 1708, for objects that have been identified as related to energy, specific energy information is gathered from different sources. The information can be accessed from one of a smart electric meter, an appliance, smart home equipment, IoT equipment, smart thermostats, smart speakers, in-line watt meters, home energy monitor equipment, such as those available from Sense.com or any combination thereof. The system could also instruct the user to turn on or off certain items in their house to better quantify energy consumed by a targeted appliance. Optionally, geographic location, weather, and orientation of a real-world space with respect to the sun may also influence the specific energy information. The energy consumption from non-renewable energy sources defines a carbon footprint for real-world space.

In one example, a smart meter combined with AI analyzes the power consumption at a customer's location to categorize consumption by load/appliance. The consumption may be real-time or historic. The extended reality device then visually recognizes a load/appliance category on the premises using a different AI process. Then, the smart meter data categorization is automatically selected for the recognized load/appliance based on the visually determined AI category that matches the smart meter AI-determined category.

Optionally, generic energy-related information may also be accessed. This generic energy information may be accessed from the manufacturer and information from third parties regarding energy consumption for a model, e.g., Energy Star information. The process continues to step 1710.

Next, in step 1710, for objects that have been identified as related to energy, a computer-generated indicator is generated and positioned near each of the objects to denote that specific energy-related information is available. A synthetic image, i.e., virtual reality or mixed reality image, is created by generating and positioning the computer-generated indicators near each identified object in the real-world space. In one example, the 3D rendering of the real-world image, i.e., physical space, e.g., the residence of a user or a commercial property of a user, allows users to pan through the real-world space and easily identify where an energy consuming object is based on the computer-generated indicators located throughout their real-world space. Panning can be accomplished through a variety of platforms, including a web or cellphone app (manual panning/paging) or through immersive virtual rendering available for use with an extended reality headset. The process continues to optional step 1712.

In optional step 1712, the system presents the recommendation for how to reduce energy consumption to the user. Recommendations as described above could include adjusting a thermostat, changing the setting of a refrigerator, and more. The recommendation may be putting tinting on windows, placing foliage outside, turning off fans or lights running in an empty real-world space, replacing incandescent lights with LED lights, and identifying air leaks around windows, doors, vents, and through ceilings. The process continues to step 1714.

In step 1714, a test is made to determine if a user selection of a computer-generated indicator is received. If no selection is received, the process loops back to before step 1714 as shown. Otherwise, if a user selection is received, the process flows to step 1716.

In response to a user selecting the computer-generated indicator, in step 1716, the user may adjust the energy consumption of the identified object using one or more of hand gesture recognition, voice recognition, eye tracking, or user selection of a computer-generated control overlaid in the VR environment. Optionally, generic energy information or energy consumption information may also be presented. Further, a recommendation indicator may also be presented. The process ends at 1718.

In one example, AI-assisted recommendations for strategies and solutions to improve energy consumption and carbon/inefficiency-score throughout real-world space are provided. Further, recommendations can be selected and placed in a virtual “basket” that can be used to request follow-up sales/service calls to be addressed by technicians/associates or affiliates.

In another example, the system overlays a photorealistic representation of the recommendation in the real-world space. For example, window tinting may be applied, i.e., overlaid, over the real-world image of the window. Outside foliage is recommended and presented. Image effects of photography/videography, such as lighting, color, luminesce, reflectance, etc., may be applied. Further, the window's orientation versus the sun may be determined by many means, including metadata, GPS from the image, light patterns through the window, and user input.

Another example is replacing a current washer and dryer with an energy-efficient washer and dryer. The system may overlay a photorealistic image of the replacement washer and dryer to give the user an understanding of how the end results may look. In addition, recommendations on where to purchase the replacement appliance and recommendations for installation may also be included.

In another example, the user may turn on/off an identified object related to energy consumption, such as the washer and dryer. This may help to understand the amount of energy used in real-time when disaggregating energy consumption from a smart meter. The identified object is controlled as an IoT device. Another example is a smart thermostat, such as a Next thermostat, which is an IoT device that can be remotely controlled over the Internet, not just turned on or off but set to a specific temperature to measure heating or cooling energy consumption.

This ability to turn on/off the identified object related to energy if it does not connect as an IoT device could be simulated based on the manufacturer's specification and whether age or condition (e.g., age or condition of an AC unit) needs to be taken into account for efficiency. This energy information is presented to the user.

The overlaying of photorealistic images includes inserting the replacement washer and dryer with image editing software that uses a resizing transformation to be consistent with the scene surrounding the objects in the real-world image.

In some examples, coupons, discounts, partnerships, and energy rebates are presented along with the recommendations.

Budgets may also be set so that recommendations are ranked in terms of the highest energy savings for the lowest cost to stay within a consumer's budget. Stated differently, potential energy savings, carbon/energy inefficiency, and energy recommendations can be optimized for budgets. With all available carbon/energy inefficiency recommendations in hand, customers can experiment with the best allocation of their investment by allowing them to enter their budget and automatically calculate the best places to invest in optimizing carbon/efficiency. Further, a what-if tool allows the user to evaluate the optimum carbon/energy efficiency improvements for any given disposable budget and estimated energy bill savings.

The goal to reduce energy consumption and reduce carbon footprint can be “gamified” to allow consumers to publish their carbon/efficiency score on social media or in the virtual space they use to interact with friends and family (i.e., Facebook, Instagram, Tiktok, Roblox, Sandbox.com and more) with before/after story-lines.

### Computer Hardware

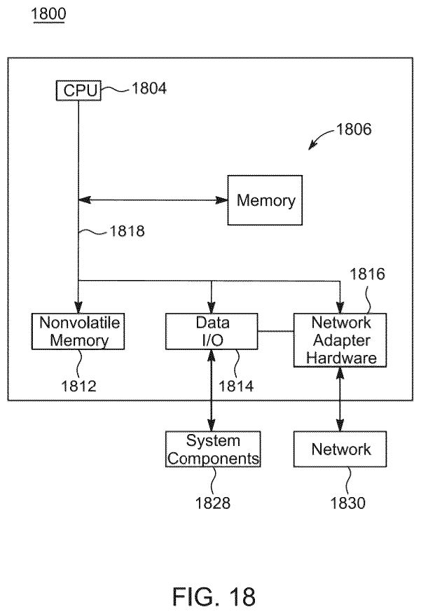

FIG. 18 illustrates a block diagram illustrating a processor 1800 according to an example. The processor 1800 is an example of a processing subsystem that is able to perform any of the above-described processing operations, control operations, other operations, or combinations of these.

The processor 1800 in this example includes a CPU 1804 that is communicatively connected to a main memory 1806 (e.g., volatile memory), a non-volatile memory 1812 to support processing operations. The CPU 1804 is further communicatively coupled to a network adapter hardware 1816 to support input and output communications with external computing systems such as through the illustrated network 1830.

The processor 1800 further includes a data input/output (I/O) processor 1814 that can be adapted to communicate with any type of equipment, such as the illustrated system components 1828. The data input/output (I/O) processor, in various examples, can be configured to support any type of data communications connection, including present-day analog and/or digital techniques or via a future communications mechanism. A system bus 1818 interconnects these system components.

### Information Processing System

The present subject matter can be realized in hardware, software, or a combination of hardware and software. A system can be realized in a centralized fashion in one computer system or in a distributed fashion where different elements are spread across several interconnected computer systems. Any kind of computer system—or other apparatus adapted for carrying out the methods described herein-is suitable. A typical combination of hardware and software could be a general-purpose computer system with a computer program that, when being loaded and executed, controls the computer system such that it carries out the methods described herein.

The present subject matter can also be embedded in a computer program product, which comprises all the features enabling the implementation of the methods described herein, and which—when loaded in a computer system—is able to carry out these methods. Computer program in the present context means any expression, in any language, code, or notation, of a set of instructions intended to cause a system having an information processing capability to perform a particular function either directly or after either or both of the following a) conversion to another language, code or, notation; and b) reproduction in a different material form.

Each computer system may include, inter alia, one or more computers and at least a computer-readable medium allowing a computer to read data, instructions, messages or message packets, and other computer-readable information from the computer-readable medium. The computer-readable medium may include computer-readable storage medium embodying non-volatile memory, such as read-only memory (ROM), flash memory, disk drive memory, CD-ROM, and other permanent storage. Additionally, a computer medium may include volatile storage such as RAM, buffers, cache memory, and network circuits. Furthermore, the computer-readable medium may comprise computer-readable information in a transitory state medium such as a network link and/or a network interface, including a wired network or a wireless network, that allows a computer to read such computer-readable information. In general, the computer-readable medium embodies a computer program product as a computer-readable storage medium that embodies computer-readable program code with instructions to control a machine to perform the above-described methods and realize the above-described systems.

### Non-Limiting Examples

Although specific embodiments of the subject matter have been disclosed, those having ordinary skill in the art will understand that changes can be made to the specific embodiments without departing from the spirit and scope of the disclosed subject matter. The scope of the disclosure is not to be restricted, therefore, to the specific embodiments, and it is intended that the appended claims cover any and all such applications, modifications, and embodiments within the scope of the present disclosure.

Although specific embodiments of the invention have been discussed, those having ordinary skill in the art will understand that changes can be made to the specific embodiments without departing from the scope of the invention. The scope of the invention is not to be restricted, therefore, to the specific embodiments, and it is intended that the appended claims cover any and all such applications, modifications, and embodiments within the scope of the present invention.

It should be noted that some features of the present invention may be used in one embodiment thereof without the use of other features of the present invention. As such, the foregoing description should be considered as merely illustrative of the principles, teachings, examples, and exemplary embodiments of the present invention and not a limitation thereof.

Also, these embodiments are only examples of the many advantageous uses of the innovative teachings herein. In general, statements made in the specification of the present application do not necessarily limit any of the various claimed inventions. Moreover, some statements may apply to some inventive features but not to others.

The description of the present invention has been presented for purposes of illustration and description and is not intended to be exhaustive or limited to the invention in the form disclosed. Many modifications and variations will be apparent to those of ordinary skill in the art without departing from the scope and spirit of the described embodiments. The embodiment was chosen and described in order to best explain the principles of the invention and its practical application and to enable others of ordinary skill in the art to understand the invention for various embodiments with various modifications as are suited to the particular use contemplated. The terminology used herein was chosen to best explain the principles of the embodiments, the practical application or technical improvement over technologies found in the marketplace, or to enable others of ordinary skill in the art to understand the embodiments disclosed herein.

1. A computer-implemented method for controlling the energy consumption of an object in an extended reality space, the method comprising:
accessing at least one image of a real-world space;
identifying, using image recognition, an object related to energy consumption in the at least one image in the real-world space;
storing a 3D coordinate of the identified object related to energy consumption in the at least one image;
using the identified object related to energy consumption to access corresponding specific energy information, wherein the specific energy information is a real-time or historical energy consumption, measured with a measuring device, for the identified object that is independent of generic energy information for a family or model of the identified object;
creating a virtual reality image or mixed reality image by overlaying a computer-generated indicator near the identified object within the at least one image of the real-world space using the stored 3D coordinates;
receiving a user selection of the computer-generated indicator;
in response to receiving the user selection of the computer-generated indicator, presenting the specific energy information corresponding to the identified object as part of the virtual reality image or the mixed reality image; and
adjusting, by the user, the energy consumption of the identified object through a wired or wireless communication interface to control the identified object.

2. The method of claim 1, wherein the specific energy information is a real-time or historical energy consumption information, measured with the measuring device that is a smart meter coupled to a plurality of parallel coupled energy consumption related objects, including the identified object, wherein the measuring device analyzes a power consumption of the plurality of parallel coupled energy consumption related objects to determine the energy consumption of the identified object.

3. The method of claim 1, wherein the specific energy information is a real-time or historical energy consumption, measured with the measuring device that is an on-call device coupled to the identified object.

4. The method of claim 1, wherein the accessing the at least one image of the real-world space includes accessing at least one of a real-world image, a virtual image, and a combination thereof.

5. The method of claim 1, wherein the identifying the identified object related to energy consumption in the at least one image of the real-world space includes one of receiving input from a user labeling the identified object in the at least one image, image recognition of the identified object in the at least one image, or a combination thereof.

6. The method of claim 5, wherein the using the identified object related to energy consumption to access corresponding specific energy information, includes accessing energy consumption information from one of a smart electric meter, an appliance, smart home equipment, Internet of Thing equipment, smart thermostat, smart speaker, in-line watt meter, or any combination thereof.

7. The method of claim 5, wherein the image recognition of the identified object related to energy consumption in the at least one image includes identifying one of appliances, HVAC, windows, range hoods, thermostats, doors, structural features, ceilings, HVAC vents, pool pumps, sprinkler pumps, or a combination thereof.

8. The method of claim 1, wherein the specific energy information corresponding to the identified object related to energy consumption, includes presenting generic energy information from one of a manufacturer of the identified object, information from third parties regarding energy consumption for a model of the identified object, or a combination of both.

9. The method of claim 1, wherein the presenting the specific energy information corresponding to the identified object, includes creating another synthetic image by combining the specific energy information with the at least one image of the real-world space.

10. The method of claim 1, wherein the accessing of the at least one image of the real-world space includes accessing one of a 2-D image, a 3-D image from LiDAR, photogrammetry stitching, or generation of a point cloud.

11. The method of claim 1, wherein the accessing of the at least one image of the real-world space includes accessing images in an infrared frequency range to identify differences in heat.

12. The method of claim 1, further comprising:
accessing historical data of energy consumption of the identified object;
analyzing user behavior patterns and preferences based on the historical data;
applying machine learning algorithms to identify correlations between energy consumption and user behavior patterns;
generating recommendations for the identified object based on the identified correlations; and
presenting the recommendations as part of the specific energy information corresponding to the identified object.

13. The method of claim 12, wherein the recommendations include advertisements from a third-party to implement the recommendations.

14. A system for controlling the energy consumption of an object in an extended reality space, the system comprising:
a computer memory capable of storing machine instructions; and
a hardware processor in communication with the computer memory, the hardware processor configured to access the computer memory to execute the machine instructions for performing:
accessing at least one image of a real-world space;
identifying, using image recognition, an object related to energy consumption in the at least one image in the real-world space;
storing a 3D coordinate of the identified object related to energy consumption in the at least one image;
using the identified object related to energy consumption to access corresponding specific energy information, wherein the specific energy information is a real-time or historical energy consumption, measured with a measuring device, for the identified object that is independent of generic energy information for a family or model of the identified object;
creating a virtual reality image or mixed reality image by overlaying a computer-generated indicator near the identified object within the at least one image of the real-world space using the stored 3D coordinates;
receiving a user selection of the computer-generated indicator;
in response to receiving the user selection of the computer-generated indicator, presenting the specific energy information corresponding to the identified object as part of the virtual reality image or the mixed reality image; and
adjusting, by the user, the energy consumption of the identified object through a wired or wireless communication interface to control the identified object.

15. The system of claim 14, wherein the specific energy information is a real-time or historical energy consumption information, measured with the measuring device that is a smart meter coupled to a plurality of parallel coupled energy consumption related objects, including the identified object, wherein the measuring device analyzes a power consumption of the plurality of parallel coupled energy consumption related objects to determine the energy consumption of the identified object.

16. The system of claim 14, wherein the specific energy information is a real-time or historical energy consumption, measured with the measuring device that is an on-call device coupled to the identified object.

17. The system of claim 14, wherein the accessing the at least one image of the real-world space includes accessing at least one of a real-world image, a virtual image, and a combination thereof.

18. The system of claim 14, wherein the identifying the identified object related to energy consumption in the at least one image of the real-world space includes one of receiving input from a user labeling the identified object in the at least one image, image recognition of the identified object in the at least one image, or a combination thereof.

19. The system of claim 18, wherein the using the identified object related to energy consumption to access corresponding specific energy information, includes accessing energy consumption information from one of a smart electric meter, an appliance, smart home equipment, Internet of Thing equipment, smart thermostat, smart speaker, in-line watt meter, or any combination thereof.

20. The system of claim 18, wherein the image recognition of the identified object related to energy consumption in the at least one image includes identifying one of appliances, HVAC, windows, range hoods, thermostats, doors, structural features, ceilings, HVAC vents, pool pumps, sprinkler pumps, or a combination thereof.
